(19) United States
(12) Patent Application Publication
(10) Pub. No.: US 2015/0144266 A1
(43) Pub. Date: May 28, 2015

(54) SUBSTRATE PROCESSING APPARATUS

(71) Applicant: TOKYO ELECTRON LIMITED, Tokyo (JP)

(72) Inventors: Nobuhiro WADA, Nirasaki City (JP); Makoto KOBAYASHI, Hsin-chu (TW); Hiroshi TSUJIMOTO, Nirasaki City (JP); Jun TAMURA, Nirasaki City (JP); Mamoru NAOI, Nirasaki City (JP)

(21) Appl. No.: 14/600,288

(22) Filed: Jan. 20, 2015

Related U.S. Application Data
(62) Division of application No. 13/160,053, filed on Jun. 14, 2011.
(60) Provisional application No. 61/360,682, filed on Jul. 1, 2010.

(30) Foreign Application Priority Data
Jun. 14, 2010 (JP) 2010-134991

(51) Int. Cl. H01J 37/32

(52) U.S. Cl. CPC H01J 37/32568; H01J 37/32027
USPC 156/345.44

(57) ABSTRACT

The substrate processing apparatus includes a lower electrode on which a substrate is capable of being held, a high frequency power source electrically connected to the lower electrode, an upper electrode facing the lower electrode, a plasma processing space being formed between the lower electrode and the upper electrode, wherein the upper electrode includes an inner upper electrode facing a center portion of the lower electrode and an outer upper electrode facing a circumferential portion of the lower electrode, the inner electrode and the outer electrode being electrically insulated from each other, a first direct current power source electrically connected to the inner upper electrode to apply a positive direct current voltage, and a dielectric member covering a bottom surface of the upper electrode, the dielectric member facing the lower electrode with the plasma processing space in-between.

### CROSS-REFERENCE TO RELATED PATENT APPLICATIONS

This application is a divisional application of prior U.S. application Ser. No. 13/160,053, filed Jun. 14, 2011, the entire contents of which are incorporated herein by reference, and this application claims the benefit of Japanese Patent Application No. 2010-134991, filed on Jun. 14, 2010, in the Japan Patent Office, and U.S. Patent Application No. 61/360,682, filed on Jul. 1, 2010, in U.S. Patent and Trademark Office, the disclosures of which are incorporated herein in its entirety by reference.

### BACKGROUND OF THE INVENTION

1. Field of the Invention

The present invention relates to a substrate processing apparatus for performing a plasma process on a substrate.

2. Description of the Related Art

In a conventional substrate processing apparatus including a lower electrode and an upper electrode disposed in parallel with the lower electrode, plasma is generated in a processing space between the lower and upper electrodes to perform a desired plasma process on a substrate, for example, a wafer for a semiconductor device (hereinafter, referred to as ‘wafer’), the substrate is held on the lower electrode.

However, distribution of plasma density in the processing space may greatly affect uniformity in the plasma process performed on the wafer, and thus, several technologies for improving the distribution of the plasma density in the processing space are suggested.

For example, an upper electrode is divided into an inner electrode and an outer electrode, and when a direct current (DC) voltage is applied to each of the inner and outer electrodes, a difference may be generated between an electric potential of the inner electrode and an electric potential of the outer electrode (for example, refer to Patent Document 1). When a negative DC voltage is applied to the upper electrode that is formed of a semiconductor material such as silicon, positive ions are dragged to the upper electrode, and then, the upper electrode discharges secondary electrons generated due to a collision with the positive ions, so that the secondary electrons flow into the plasma in the processing space. In addition, a current flows from a DC power source to the upper electrode in order to preserve the discharged secondary electrons. The discharged secondary electrons change the distribution of the plasma density; however, a difference between the electric potentials of the inner electrode and the outer electrode is generated, and accordingly, the number of positive ions dragged to each of the inner and outer electrodes, and further, the number of discharged secondary electrons are adjusted to improve the distribution of the plasma density.

However, according to the technology disclosed in Patent Document 1, the positive ions are dragged actively, each of the inner electrode and the outer electrode is sputtered by the positive ions and damaged. In addition, the upper electrode is heated by Joule heat that is generated by the electrons flowed into the plasma, and thus, the upper electrode may be damaged more.

In addition, the DC current may be unstabled according to a surface state of a portion, to which the upper electrode or the secondary electrons are grounded, and thus a reproducibility of the characteristics of the plasma process degrades. That is, performance of the plasma process is not stable.

Also, in order to reduce an excessive number of secondary electrons in the processing space, a part, for example, a ground electrode, for grounding the secondary electrons in a DC manner needs to be provided in a processing chamber including the processing space. [Patent Document 1] Japanese Laid-open Patent Publication No. 2006-286814

### SUMMARY OF THE INVENTION

To solve the above and/or other problems, the present invention provides a substrate processing apparatus and a substrate processing method that may prevent an upper electrode from being worn, stabilize performance of a plasma process, and improve a controllability of a density distribution of plasma in a processing space.

According to an aspect of the present invention, there is provided a substrate processing apparatus including a lower electrode on which a substrate is capable of being held, a high frequency power source electrically connected to the lower electrode, an upper electrode facing the lower electrode, a plasma processing space being formed between the lower electrode and the upper electrode, wherein the upper electrode includes an inner upper electrode facing a center portion of the lower electrode and an outer upper electrode facing a circumferential portion of the lower electrode, the inner electrode and the outer electrode being electrically insulated from each other, a first direct current power source electrically connected to the inner upper electrode to apply a positive direct current voltage, and a dielectric member covering a bottom surface of the upper electrode, the dielectric member facing the lower electrode with the plasma processing space in-between.

Additional objects and advantages of the invention will be set forth in the description which follows, and in part will be obvious from the description, or may be learned by practice of the invention.

The objects and advantages of the invention may be realized and obtained by means of the instrumentalities and combinations particularly pointed out hereinafter.

### BRIEF DESCRIPTION OF THE DRAWINGS

The above and other features and advantages of the present invention will become more apparent by describing in detail exemplary embodiments thereof with reference to the attached drawings in which:

FIG. 1 is a schematic cross-sectional view of a substrate processing apparatus according to an embodiment of the present invention;

FIG. 2 is a schematic view showing an electric circuit about a high frequency power for generating plasma, in the substrate processing apparatus of FIG. 1;

FIG. 3 is a graph showing an example of improving uniformity of an etching rate in the substrate processing apparatus of FIG. 1;

FIG. 4 is a graph showing another example of improving uniformity of the etching rate in the substrate processing apparatus of FIG. 1;

FIG. 5 is a schematic cross-sectional view of a substrate processing apparatus according to another embodiment of the present invention;

FIG. 6 is a schematic view showing an electric circuit about a high frequency power for generating plasma, in the substrate processing apparatus of FIG. 5;

FIG. 7 is a graph showing a voltage characteristic of a capacity-variable filter shown in FIG. 6;

FIG. 8 is a schematic cross-sectional view of a substrate processing apparatus according to another embodiment of the present invention; and

FIG. 9 is a schematic view showing an electric circuit about a high frequency power for generating plasma, in the substrate processing apparatus of FIG. 8.

### EXPLANATION ON REFERENCE NUMERALS

W: wafer

PS: processing space

10, 34, 36: substrate processing apparatus

12: susceptor

18: first high frequency power source

28: upper electrode plate

28a: inner electrode

28b: outer electrode

33: second variable DC power source

35: capacity-variable filter

37: third variable DC power source

### DETAILED DESCRIPTION OF THE INVENTION

Hereinafter, the present invention will be described in detail by explaining exemplary embodiments of the invention with reference to the attached drawings.

A substrate processing apparatus according to an embodiment of the present invention will be described.

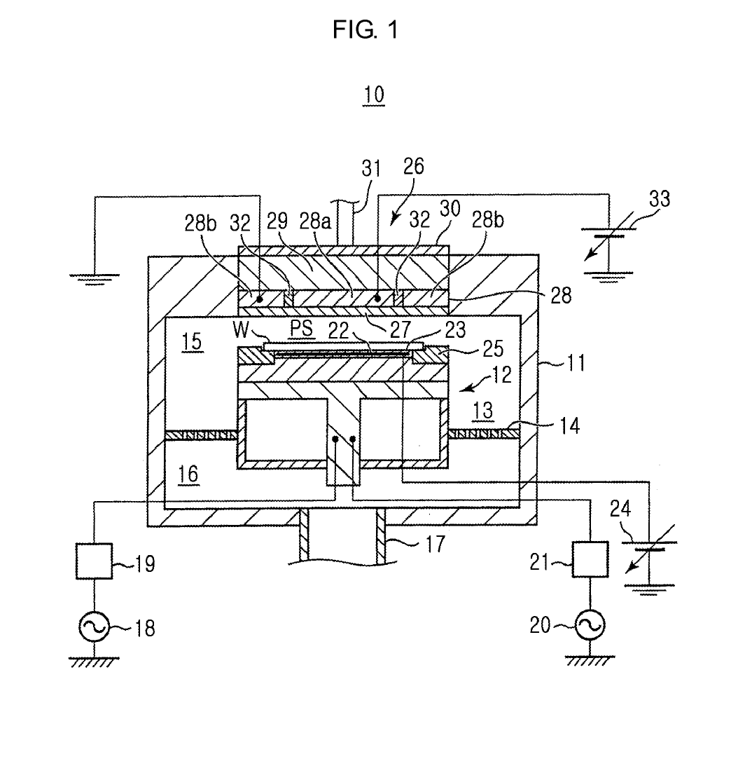

FIG. 1 is a schematic cross-sectional view of the substrate processing apparatus according to the present embodiment. The substrate processing apparatus of the present embodiment performs a plasma etching process on a wafer, that is, a substrate.

Referring to FIG. 1, a substrate processing apparatus 10 includes a chamber 11 receiving a wafer W having a diameter of, for example, 300 mm, and the chamber 11 includes a cylindrical susceptor 12 (lower electrode), on which the wafer W for a semiconductor device is held. In the substrate processing apparatus 10, a side exhaust path 13 is formed by an inner side wall of the chamber 11 and a side surface of the susceptor 12. An exhaust plate 14 is disposed in an intermediate portion of the side exhaust path 13.

The exhaust plate 14 is a plate-shaped member having a plurality of through holes, and serves as a partition plate dividing inside of the chamber 11 into an upper portion and a lower portion. In the upper portion 15 (hereinafter, referred to as a processing chamber) of the chamber 11, which is divided by the exhaust plate 14, the plasma is generated as will be described later. In addition, an exhaust pipe 17 for exhausting gas in the chamber 11 is connected to the lower portion 16 (hereinafter, referred to as an exhaust chamber (manifold)) of the chamber 11. The exhaust plate 14 captures or reflects the plasma generated in the processing chamber 15 to prevent leakage of the plasma to the manifold 16.

A turbo molecular pump (TMP) and a dry pump (DP) (both are not shown) are connected to the exhaust pipe 17, and the TMP and DP depressurize the inside of the chamber 11 by performing a vacuum suction. In addition, a pressure in the chamber 11 is controlled by an APC valve (not shown).

A first high frequency power source 18 is connected to the susceptor 12 in the chamber 11 via a first matcher 19, and a second high frequency power source 20 is connected to the susceptor 12 via a second matcher 21. The first high frequency power source 18 supplies an high frequency power of a relatively high frequency, for example, 40 MHz, for plasma generation to the susceptor 12, and the second high frequency power source 20 supplies an high frequency power of a relatively low frequency, for example, 2 MHz, for dragging ions to the susceptor 12. Accordingly, the susceptor 12 serves as a lower electrode. In addition, the first matcher 19 and the second matcher 21 reduce reflection of the high frequency power from the susceptor 12 in order to maximize an efficiency of supplying the high frequency power to the susceptor 12.

An upper portion of the susceptor 12 has a shape in which a cylinder having a smaller diameter coaxially protrudes from a front end of a cylinder having a larger diameter, and a step surrounding the cylinder having the smaller diameter is formed in the upper portion of the susceptor 12. An electrostatic chuck 23 formed of ceramics, which includes an electrostatic electrode plate 22 therein, is disposed on a front end of the cylinder having the smaller diameter. A first variable direct current (DC) power source 24 is connected to the electrostatic electrode plate 22. When a positive DC voltage is applied from the first variable DC power source 24 to the electrostatic electrode plate 22, negative electric potential is generated on a surface (hereinafter, referred to as a rear surface) of the wafer W facing the electrostatic chuck 23 so that a potential difference is generated between the electrostatic electrode plate 22 and the rear surface of the wafer W. The wafer W is absorbed and held on the electrostatic chuck 23 by Coulomb force or Johnson-Rahbek force caused by the potential difference.

In addition, in the upper portion of the susceptor 12, a focus ring 25 is held on the step formed in the upper portion of the susceptor 12 so as to surround the wafer W absorbed and held on the electrostatic chuck 23. The focus ring 25 is formed of Si. That is, since the focus ring 25 is formed of a semiconductor, a distribution area of the plasma may be expanded to an upper surface of the focus ring 25, as well as on the upper surface of the wafer W.

A shower head 26 is disposed on a ceiling of the chamber 11 so as to face the susceptor 12 in a state where a processing space (PS) is disposed between the shower head 26 and the susceptor 12. The shower head 26 includes a dielectric plate 27 (dielectric member), an upper electrode plate 28 (upper electrode), a cooling plate 29 which detachably supports the upper electrode plate 28 in a state of being hanged, and a cover body 30 covering the cooling plate 29.

The dielectric plate 27 is a disc-shaped member formed of an insulating material having a plasma resistance, for example, ceramics such as silica (SiO₂), silicon carbide (SiC), or yttria (Y₂O₃), glass such as quartz, or crystals, and entirely covers a surface of the upper electrode plate 28, which faces the processing space PS, that is, a lower surface of the upper electrode plate 28. The upper electrode plate 28 is a disc-shaped member formed of a semiconductor, for example, silicon. The dielectric plate 27 and the upper electrode plate 28 include a plurality of gas holes (not shown) which penetrate through the dielectric plate 27 and the upper electrode plate 28 and communicate with a buffer chamber in the cooling plate 29, which will be described later. In addition, the buffer chamber (not shown) is formed in the cooling plate 29, and a processing gas is supplied to the buffer chamber through a processing gas supplying pipe 31 from a processing gas supplying apparatus (not shown). The processing gas supplying apparatus, for example, generates a mixed gas by appropriately adjusting a ratio of flow rates of various gases, and introduces the mixed gas into the processing space PS through the processing gas supplying pipe 31, the buffer chamber, and the gas holes.

In addition, the upper electrode plate 28 of the shower head 26 is divided into an inner electrode 28a which faces a center portion of the wafer W held on the susceptor 12, and an outer electrode 28b which faces a circumferential portion of the wafer W, and an insulating ring 32 that is an annular insulating member for electrically insulating the inner electrode 28a and the outer electrode 28b from each other is disposed between the inner electrode 28a and the outer electrode 28b. A second variable DC power source 33 is connected to the inner electrode 28a to apply a positive DC voltage to the inner electrode 28a. The second variable DC power source 33 may change a value of the DC voltage to be applied to the inner electrode 28a, and thus, an electric potential of the inner electrode 28a may be changed. In addition, the outer electrode 28b is electrically grounded without being connected to a DC power source or the like.

In the substrate processing apparatus 10, the processing gas introduced in the processing space PS is excited by the high frequency power for generating plasma, which is applied to the processing space PS from the first high frequency power source 18 through the susceptor 12, and becomes the plasma. Positive ions in the plasma are dragged to the wafer W to perform a plasma etching process on the wafer W. Here, since the upper electrode plate 28 is covered by the dielectric plate 27, the upper electrode plate 28 is not sputtered by the positive ions and is not worn.

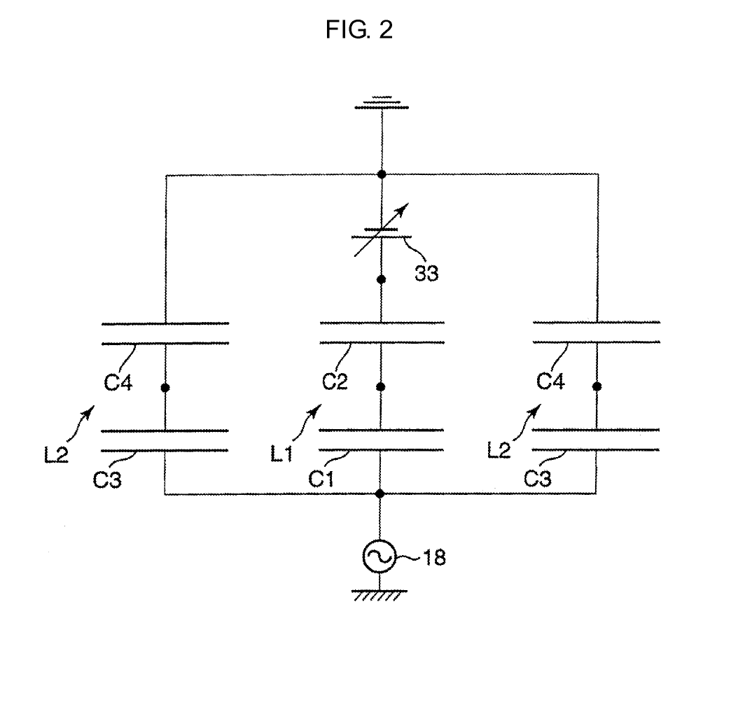

FIG. 2 is a schematic diagram showing an electric circuit about a high frequency power for plasma generation in the substrate processing apparatus of FIG. 1.

In the electric circuit of FIG. 2, a first path L1 from the first high frequency power source 18 to a ground through the processing space PS, the inner electrode 28a, and the second variable DC power source 33 and a second path L2 from the first high frequency power source 18 to the ground through the processing space PS and the outer electrode 28b exist between the first high frequency power source 18 and the ground, and the first path L1 and the second path L2 are connected to each other in parallel.

In the first path L1, the processing space PS and the inner electrode 28a may be respectively considered as a condenser C1 and a condenser C2 that are connected to each other in series. In the second path L2, the processing space PS and the outer electrode 28b may be respectively considered as a condenser C3 and a condenser C4 that are connected to each other in series.

In the electric circuit of FIG. 2, since the second variable DC power source 33 is disposed between the condenser C2 and the ground in the first path L1 and applies the positive DC voltage to the condenser C2 (the inner electrode 28a), a sum of the potential differences of the condenser C1 and the condenser C2 is less than that of the potential differences of the condenser C3 and the condenser C4. As a result, the potential difference of the condenser C1 becomes less than that of the condenser C3. Here, the potential difference of the condenser C1 may be considered as the potential difference between the inner electrode 28a and the suscepter 12 in the processing space PS, and the potential difference of the condenser C3 may be considered as the potential difference between the outer electrode 28b and the susceptor 12 in the processing space PS. In general, when the potential difference is large in the processing space, an electric field becomes strong and the density of plasma is increased, and when the potential difference is small in the processing space, the electric field becomes weak and the density of plasma is reduced.

Therefore, in the substrate processing apparatus 10, the density of plasma between the inner electrode 28a and the susceptor 12 in the processing space PS may be lower than the density of plasma between the outer electrode 28b and the susceptor 12 in the processing space PS.

In addition, in the electric circuit of FIG. 2, when the second variable DC power source 33 applies a negative DC voltage to the condenser C2 (the inner electrode 28a), the sum of the potential differences of the condenser C1 and the condenser C2 becomes greater than the sum of the potential differences of the condenser C3 and the condenser C4. Therefore, the potential difference of the condenser C1 may be greater than the potential difference of the condenser C3, and accordingly, the density of plasma between the inner electrode 28a and the susceptor 12 may be higher than that between the outer electrode 28b and the susceptor 12.

That is, since the second variable DC power source 33 is disposed between the inner electrode 28a and the ground, a controllability of the distribution of the plasma density may be improved, and accordingly, uniformity of an etching rate in the plasma etching process may be improved.

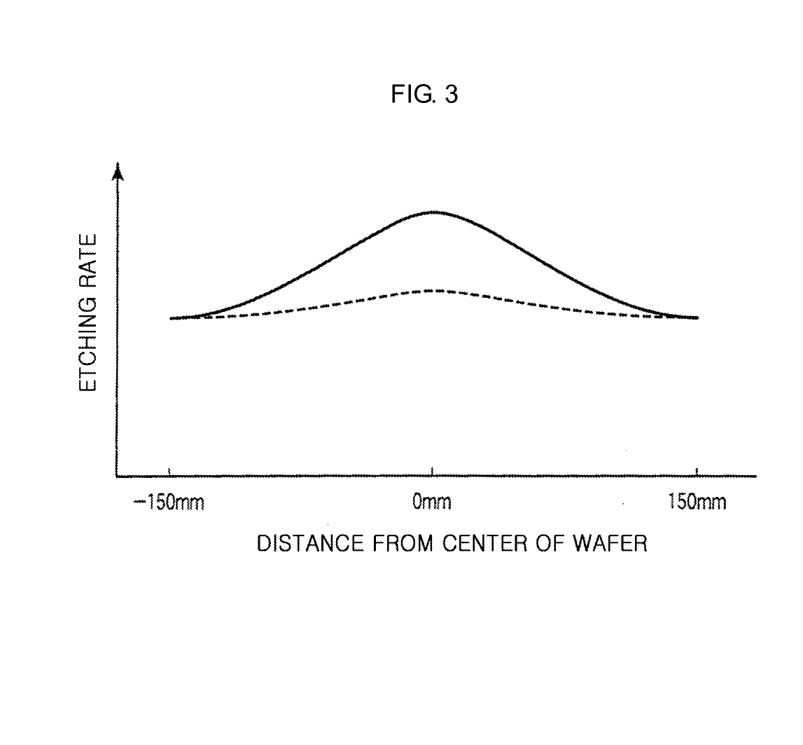

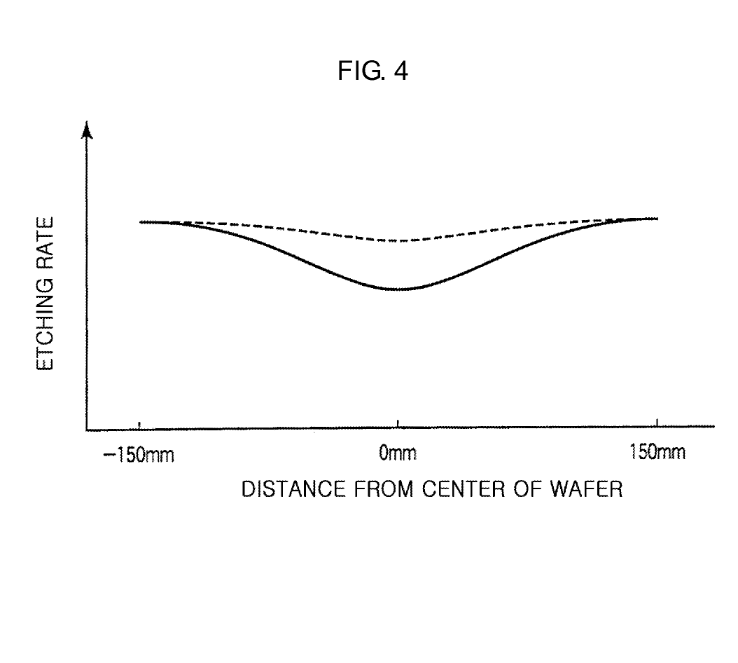

For example, when the etching rate at the center portion of the wafer W is higher than that at the circumferential portion of the wafer W in plasma etching process (refer to a solid line of FIG. 3), the density of the plasma at the center portion of the wafer W may be reduced by applying the positive DC voltage to the condenser C2 (the inner electrode 28a) from the second variable DC power source 33, and accordingly, the etching rate at the center portion of the wafer W may be lowered (refer to a broken line of FIG. 3). In addition, when the etching rate at the center portion of the wafer W is lower than the etching rate at the circumferential portion of the wafer W (refer to a solid line of FIG. 4), the density of plasma at the center portion of the wafer W may be increased by applying the negative DC voltage to the condenser C2 (the inner electrode 28a) from the second variable DC power source 33, and accordingly, the etching rate at the center portion of the wafer W may be improved (refer to a broken line of FIG. 4).

In addition, in the substrate processing apparatus 10, since an electric potential of the inner electrode 28a may be changed by the second variable DC power source 33, the sum of the potential differences of the condenser C1 and the condenser C2, and moreover, the potential difference of the condenser C1 (the potential difference between the inner electrode 28a and the susceptor 12) may be actively changed. Here, when a value of the DC voltage to be applied to the inner electrode 28a is changed according to processing conditions of the plasma etching process, for example, a kind of the gas, a pressure in the processing space PS, and a magnitude of the high frequency power for plasma generation, a plasma density distribution suitable for the processing conditions of the plasma etching process between the inner electrode 28a and the susceptor 12 may be realized.

In the substrate processing apparatus 10 according to the present embodiment, since the portion of the upper electrode plate 28, which contacts the processing space PS, is covered by the dielectric plate 27, the upper electrode plate 28 is not sputtered by the positive ions. In addition, since the dielectric plate 27 blocks the electrons, the electrons do not flow into the plasma. That is, since the direct current does not flow, heating of the upper electrode plate 28 caused by Joule heat may be prevented, and wearing of the upper electrode plate 28 may be prevented. In addition, since the electrons do not excessively flow into the plasma, the direct current does not flow, and accordingly, the plasma process may be stabilized, and at the same time, a part for grounding the electrons in a DC manner does not need to be provided in the chamber 11 which includes the processing space PS.

In addition, in the substrate processing apparatus 10 according to the present embodiment, since the DC voltage is applied to the inner electrode 28a of the upper electrode plate 28 and at the same time, the outer electrode 28b of the upper electrode plate 28 is electrically grounded, the potential difference between the inner electrode 28a and the susceptor 12 and the potential difference between the outer electrode 28b and the susceptor 12 may be different from each other. When the potential difference is changed, strength of the electric field is changed, and then, the density distribution of the plasma is also changed. Thus, the density of plasma between the inner electrode 28a and the susceptor 12 and the density of plasma between the outer electrode 28b and the susceptor 12 may be different from each other. Consequently, the controllability of the density distribution of the plasma in the processing space PS may be improved.

In addition, in the substrate processing apparatus 10, since the electric potential of the inner electrode 28a may be changed, the potential difference between the inner electrode 28a and the susceptor 12 may be actively changed. Consequently, the controllability of the density distribution of the plasma between the inner electrode 28a and the susceptor 12 may be improved.

In the above-described substrate processing apparatus 10, the dielectric plate 27 may be replaced with another dielectric plate, at least one of a thickness, a dielectric constant, and a surface area of which is changed, according to the processing conditions of the plasma process. When at least one of the dielectric constant and the surface area is changed, a capacity of the condenser C1 or the condenser C3 is changed in the electric circuit of FIG. 2 and the potential difference is changed, and accordingly, the potential difference of the condenser C2 or the condenser C4 is also changed. That is, the density distribution of the plasma in the processing space PS may be changed, and thus, the controllability of the density distribution of plasma in the processing space PS may be improved.

In addition, in the substrate processing apparatus 10, the second variable DC power source 33 is connected to the inner electrode 28a and the outer electrode 28b is grounded; however, the inner electrode 28a may be grounded and a variable DC power source may be connected to the outer electrode 28b to apply the DC voltage to the outer electrode 28b, according to the processing conditions or results of the plasma etching process. Even in this case, the plasma density of the inner electrode 28a and the susceptor 12 and the plasma density of the outer electrode 28b and the susceptor 12 may be different from each other, and thus, the controllability of the density distribution of the plasma in the processing space PS may be improved.

In addition, in the substrate processing apparatus 10, the second variable DC power source 33 is connected to the inner electrode 28a; however, a fixed DC power source which applies only a predetermined value of a DC voltage may be connected to the inner electrode 28a.

Next, a substrate processing apparatus according to another embodiment of the present invention will be described in detail.

Configurations and operations of the substrate processing apparatus of the present embodiment are basically the same as those of the previous embodiment, and thus, only configurations and operations different from those of the previous embodiment will be described as follows.

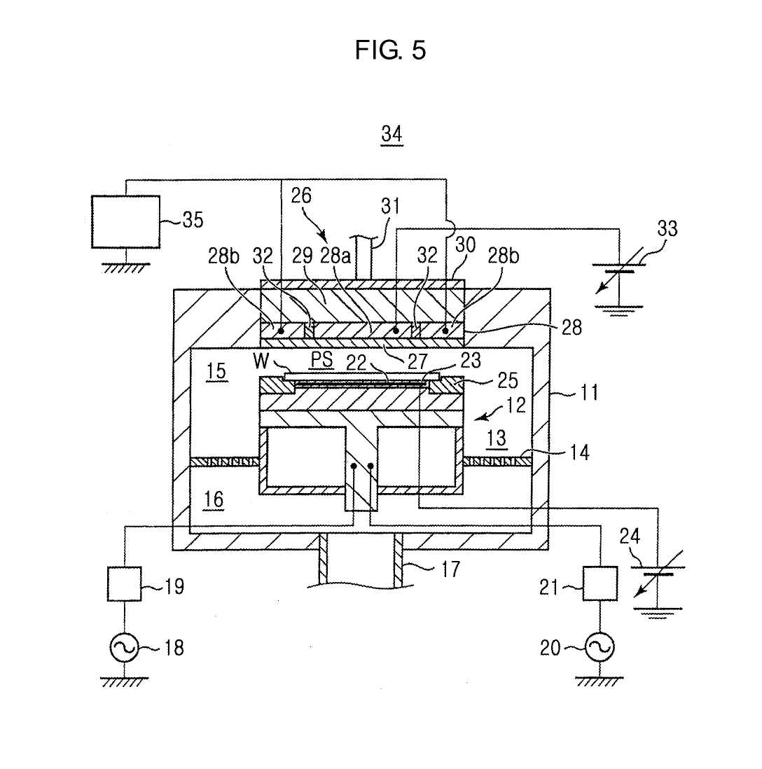

FIG. 5 is a schematic cross-sectional view of the substrate processing apparatus according to the present embodiment.

Referring to FIG. 5, in a substrate processing apparatus 34, a capacity-variable filter 35 is connected to the outer electrode 28b, and the outer electrode 28b is grounded via the capacity-variable filter 35. The capacity-variable filter 35 includes a plurality of variable condensers that are connected to each other in parallel, and serves as a high-cut filter for cutting off a high frequency current that is higher than a predetermined frequency. In addition, when a high frequency voltage is applied, capacities of the included variable condensers are changed, and thus, the potential difference of the capacity-variable filter 35 may be changed. Consequently, the electric potential of the electrode connected to the capacity-variable filter 35 may be changed.

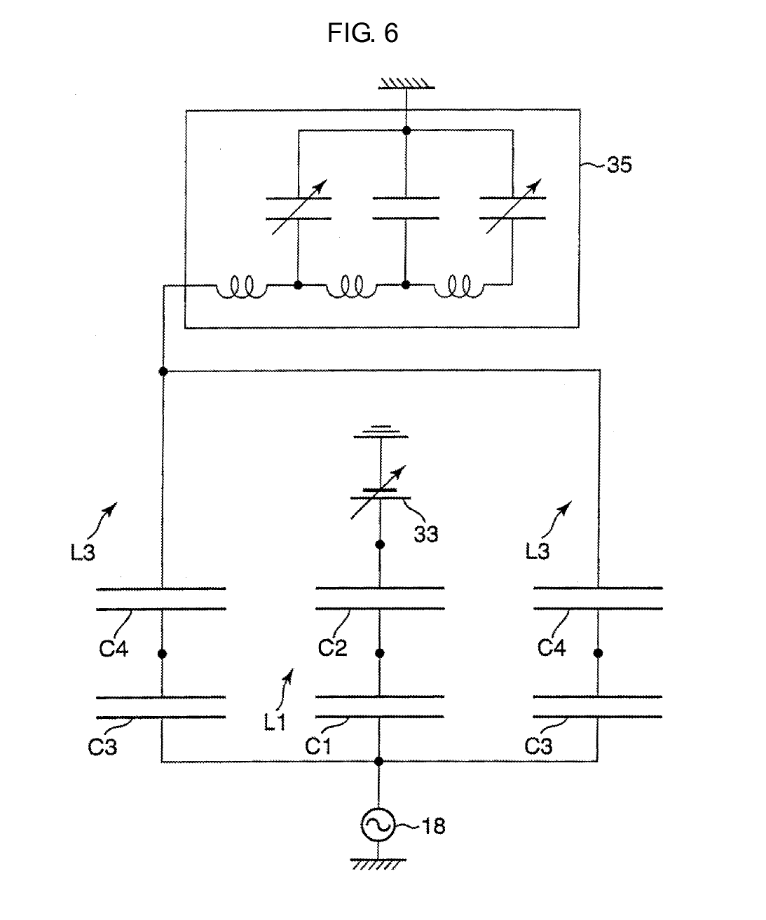

FIG. 6 is a schematic diagram showing an electric circuit about a high frequency power for generating plasma, in the substrate processing apparatus of FIG. 5.

In the electric circuit of FIG. 6, the first path L1 shown in FIG. 2 and a third path L3 from the first high frequency power source 18 to the ground via the processing space PS, the outer electrode 28b, and the capacity-variable filter 35 exist, and the first path L1 and the third path L3 are connected to each other in parallel. In the third path L3, it may be considered that the capacity-variable filter 35 is connected to the condenser C3 (processing space PS) and the condenser C4 (outer electrode 28b) in series.

In the electric circuit of FIG. 6, the capacity-variable filter 35 is disposed between the condenser C4 and the ground in the third path L3 so that the capacity-variable filter 35 changes the electric potential of the condenser C4, and thus, a sum of the potential differences of the condenser C3 and the condenser C4 may be actively changed, and moreover, the potential difference of the condenser C3 (the potential difference between the outer electrode 28b and the susceptor 12 in the processing space PS) may be actively changed. Consequently, the controllability of the density distribution of plasma between the outer electrode 28b and the susceptor 12, as well as the controllability of the density distribution of plasma between the inner electrode 28a and the susceptor 12, may be improved, and accordingly, the controllability of the density distribution of plasma in the processing space PS may be improved.

Here, in the substrate processing apparatus 34, it may be preferable that the potential difference of the condenser C3 is actively changed according to the processing conditions of the plasma etching process. Accordingly, the plasma density distribution that is suitable for the processing conditions of the plasma etching process may be realized between the outer electrode 28b and the susceptor 12.

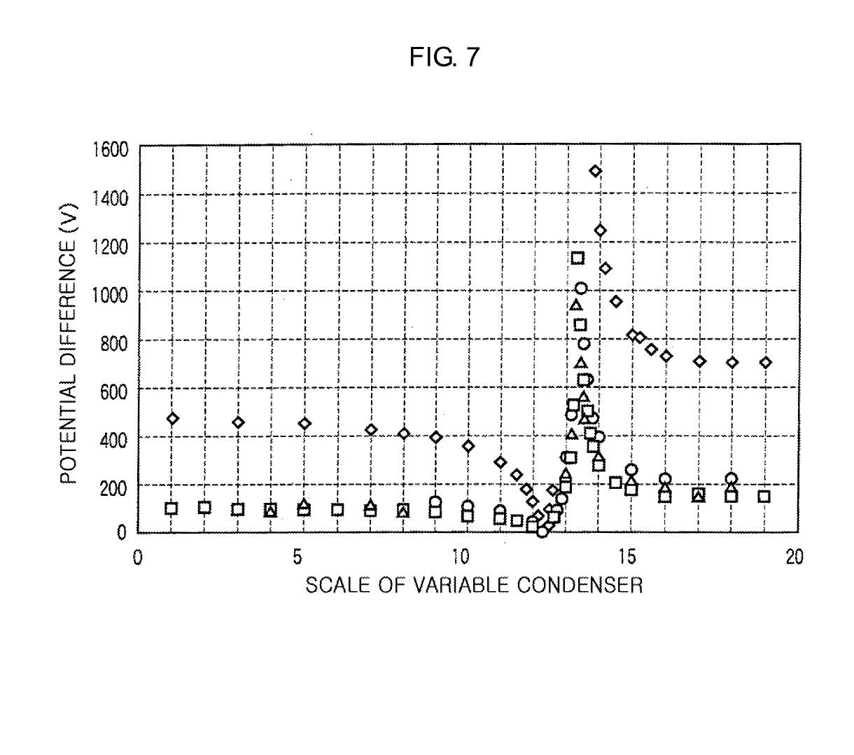

In addition, in the capacity-variable filter 35, the potential difference of the capacity-variable filter 35 may be changed by changing capacities of the variable condensers included in the capacity-variable filter 35; however, the changed capacities are represented by a scale (position) included in the capacity-variable filter 35, and the potential difference (voltage characteristic) of the capacity-variable filter 35 varies as shown in FIG. 7. Here, the voltage characteristic of the capacity-variable filter 35 includes a resonant point where the potential difference nearly becomes 0 and a resonant point where the potential difference becomes excessively large. In addition, the voltage characteristic of the capacity-variable filter 35 is changed according to the processing conditions. In FIG. 7, marks such as [symbol] , [symbol] , [symbol] or [symbol] denote the voltage characteristics under different processing conditions.

In the substrate processing apparatus 34, when the potential difference of the capacity-variable filter 35 is changed according to the processing conditions of the plasma etching process and thus the potential difference of the condenser C3 is changed, it is preferable that the potential difference of the capacity-variable filter 35 is changed within a range including a resonant point of the voltage characteristic of the capacity-variable filter 35. Accordingly, the potential difference of the condenser C3 may be largely changed, and thus, the controllability of the density distribution of plasma between the outer electrode 28b and the susceptor 12 may be greatly improved.

In the above-described substrate processing apparatus 34, the second variable DC power source 33 is connected to the inner electrode 28a and the capacity-variable filter 35 is connected to the outer electrode 28b; however, the capacity-variable filter 35 may be connected to the inner electrode 28a, and at the same time, the second variable DC power source 33 may be connected to the outer electrode 28b. Even in this case, the plasma density between the inner electrode 28a and the susceptor 12 and the plasma density between the outer electrode 28b and the susceptor 12 may be different from each other, and thus, the controllability of the plasma density distribution in the processing space PS may be improved more.

Next, a substrate processing apparatus according to another embodiment of the present invention will be described in detail.

The substrate processing apparatus of the present embodiment has basically the same configurations and operations as those of the previous embodiment, and thus only differences from the embodiment described first will be described as follows.

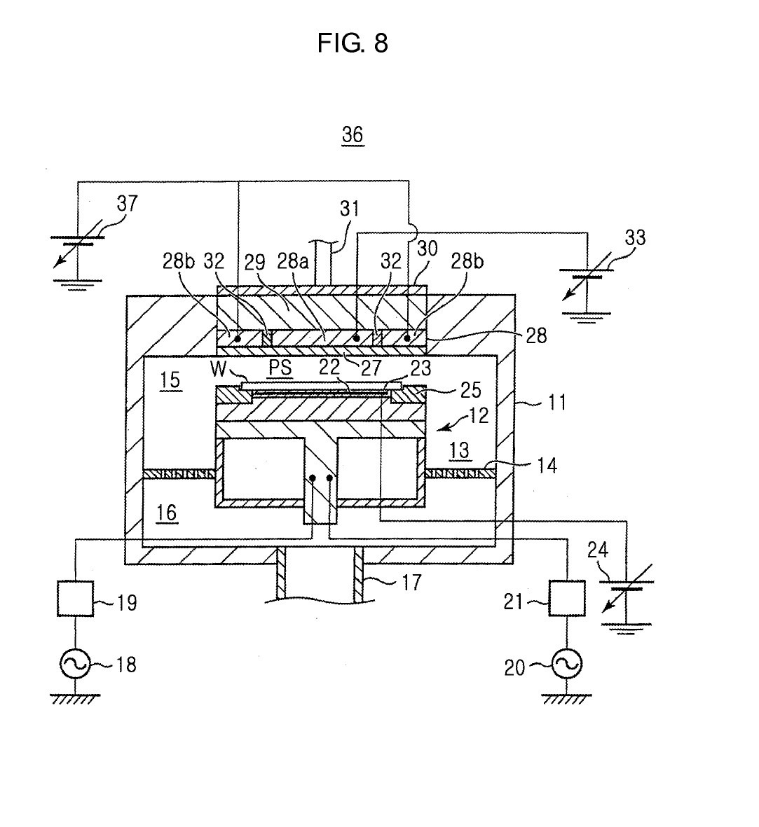

FIG. 8 is a schematic cross-sectional view of the substrate processing apparatus according to the present embodiment.

Referring to FIG. 8, in a substrate processing apparatus 36, a third variable DC power source 37 is connected to the outer electrode 28b so that a positive DC voltage is applied to the outer electrode 28b. Since the third variable DC power source 37 may change a magnitude of the DC voltage to be applied to the outer electrode 28b, the electric potential of the outer electrode 28b may be changed.

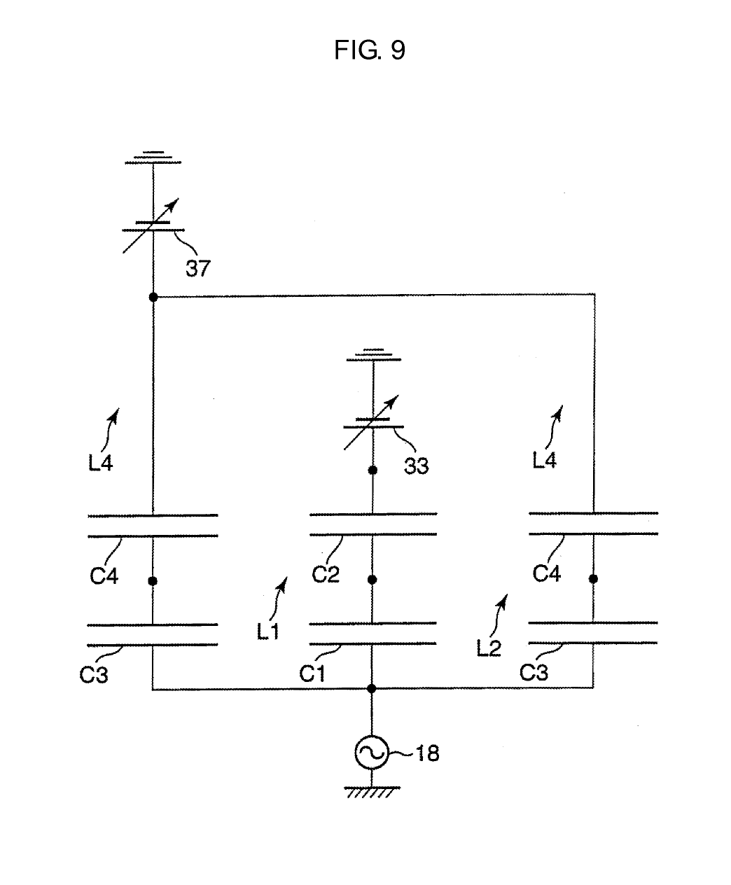

FIG. 9 is a schematic diagram of an electric circuit about a high frequency power for generating plasma, in the substrate processing apparatus of FIG. 8.

In the electric circuit of FIG. 9, the first path L1 shown in FIG. 2, and a fourth path L4 from the first high frequency power source 18 to the ground through the processing space PS, the outer electrode 28b, and the third variable DC power source 37 exist, and the first path L1 and the fourth path L4 are connected to each other in parallel. In the fourth path L4, it may be considered that the third variable DC power source 37 is connected to the condenser C3 (processing space PS) and the condenser C4 (outer electrode 28b) in series.

In the electric circuit of FIG. 9, the third variable DC power source 37 is disposed between the condenser C4 and the ground in the fourth path L4 and applies the positive DC voltage to the condenser C4. Therefore, the sum of the potential differences of the condenser C3 and the condenser C4 in this case is less than that of a case where the outer electrode 28b is directly grounded. On the other hand, when the third variable DC power source 37 applies a negative DC voltage to the condenser C4, the sum of the potential differences of the condenser C3 and the condenser C4 becomes larger.

Therefore, in the substrate processing apparatus 36, the potential difference of the condenser C3 (the potential difference between the outer electrode 28b and the susceptor 12) may be actively changed. That is, the controllability of the plasma density distribution between the outer electrode 28b and the susceptor 12, as well as the controllability of the plasma density distribution between the inner electrode 28a and the susceptor 12, may be improved, and thus, the controllability of the plasma density distribution in the processing space PS may be improved more.

In particular, when the second variable DC power source 33 applies the positive DC voltage to the condenser C2 so as to generate positive electric potential at the inner electrode 28a and the third variable DC power source 37 applies the negative DC voltage to the condenser C4 so as to generate negative electric potential at the outer electrode 28b, a difference between absolute values of the potential difference of the condenser C1 and the potential difference of the condenser C3 may become larger, and accordingly, a distribution of the etching rate which is largely lopsided may be securely improved. Alternatively, the negative DC voltage may be applied to the condenser C2 to generate the negative electric potential at the inner electrode 28a and the positive DC voltage may be applied to the condenser C4 to generate the positive electric potential at the outer electrode 28b. Even in this case, the greatly lopsided distribution of the etching rate may be securely improved.

In addition, in the substrate processing apparatus 36, the electric potential of the outer electrode 28b, as well as the electric potential of the inner electrode 28a, may be changed, and accordingly, it is preferable that the difference between the electric potentials of the inner electrode 28a and the outer electrode 28b is adjusted according to the processing conditions of the plasma etching process. Accordingly, the difference between the plasma density between the inner electrode 28a and the susceptor 12 and the plasma density between the outer electrode 28b and the susceptor 12 may be finely adjusted, and thus, the suitable plasma density distribution may be realized according to the processing conditions of the plasma etching process.

In the above-described embodiments, the upper electrode plate 28 does not move relative to the susceptor 12; however, the shower head 26 may be provided so as to be vertically movable so that the upper electrode plate 28 may move relative to the susceptor 12. In this case, the capacity of the condenser C1 or the condenser C3 in the electric circuits of FIGS. 2, 6, and 9 may be changed, and accordingly, the potential difference of the condenser C1 or the condenser C3 may be finely adjusted. Thus, the controllability of the plasma density distribution in the processing space PS may be improved more.

The substrate on which the plasma etching process is performed by the substrate processing apparatus according to each of the above-described embodiments is not limited to the wafer for semiconductor devices, and may be any of various substrates used in flat panel displays (FPDs) including liquid crystal displays (LCDs), a photomask, a CD substrate, a print substrate, or the like.

In addition, the present invention is described by using the above embodiments; however, the present invention is not limited to the above embodiments.

The objects of the present invention may be achieved by supplying a computer or the like with a recording medium having embodied thereon a software program executing the functions of the above-described embodiments so that a CPU of the computer reads and executes the program stored in the recording medium.

In this case, the program read from the recording medium executes the functions of the above-described embodiments, and thus the program and the recording medium storing the program may configure the present invention.

The recording medium for supplying the program may be any recording media, for example, RAM, NV-RAM, floppy (registered trademark) disks, hard disks, magneto-optical disks, optical disks such as CD-ROM, CD-R, CD-RW, DVD (DVD-ROM, DVD-RAM, DVD-RW, and DVD+RW), magnetic tapes, non-volatile memory cards, and other ROMs, as long as they store the program. Otherwise, the program may be downloaded from (not shown) other computers or data bases connected to the Internet, commercial networks, or local area networks.

In addition, not only the CPU of the computer may execute the read program to perform the functions of the above-described embodiments, but also an OS (operating system) or the like operating in the CPU may perform a part or all of the actual processes according to the command of the program to perform the functions of the above-described embodiments.

Also, the program read from the recording medium may be written in a memory included in a function-extension board inserted into the computer or a function-extension unit connected to the computer, and then a CPU or the like included in the function-extension board or the function-extension unit may perform a part or all of the actual processes according to the command of the program, in order to execute the functions of the above-described embodiments.

The program may be realized as an object code, a program executed by an interpreter, or script data supplied to an OS.

According to the present invention, a surface of an upper electrode, which faces a processing space, is covered by a dielectric member, and thus, the upper electrode is not sputtered by positive ions. In addition, since the dielectric member blocks electrons, the electrons do not flow into plasma. That is, since a direct current does not flow, heating of the upper electrode due to the Joule heat may be prevented, and thus, damage of the upper electrode may be prevented. In addition, since the electrons do not excessively flow into the plasma, the direct current does not flow, and accordingly, the plasma process may be stabilized and a part for grounding the electrons does not need to be provided in the processing space.

In addition, according to the present invention, a DC voltage is applied to an inner electrode of the upper electrode and an outer electrode of the upper electrode is electrically grounded, and thus, the potential difference between the inner electrode and a lower electrode and the potential difference between the outer electrode and the lower electrode may be different from each other. When the potential difference is changed, a plasma density distribution is also changed, and thus, the plasma density between the inner electrode and the lower electrode and the plasma density between the outer electrode and the lower electrode may be different from each other. Consequently, the controllability of the plasma density distribution in the processing space may be improved.

While this invention has been particularly shown and described with reference to exemplary embodiments thereof, it will be understood by those skilled in the art that various changes in form and details may be made therein without departing from the spirit and scope of the invention as defined by the appended claims.

What is claimed is:

1. A substrate processing apparatus comprising;
a lower electrode on which a substrate is capable of being held;
a high frequency power source electrically connected to the lower electrode;
an upper electrode facing the lower electrode, a plasma processing space being formed between the lower electrode and the upper electrode, wherein the upper electrode includes an inner upper electrode facing a center portion of the lower electrode and an outer upper electrode facing a circumferential portion of the lower electrode, the inner electrode and the outer electrode being electrically insulated from each other;
a first direct current power source electrically connected to the inner upper electrode to apply a positive direct current voltage; and
a dielectric member covering a bottom surface of the upper electrode, the dielectric member facing the lower electrode with the plasma processing space in-between.

2. The substrate processing apparatus of claim 1, wherein the outer electrode is electrically grounded.

3. The substrate processing apparatus of claim 1, wherein the first direct current power source includes a variable direct current power source.

4. The substrate processing apparatus of claim 1, further comprising: a capacity-variable filter connected to the outer upper electrode, wherein the outer upper electrode is electrically grounded via the capacity variable filter.

5. The substrate processing apparatus of claim 1, further comprising: a second direct current power source connected to the outer upper electrode to apply a positive direct current voltage to the outer upper electrode.

6. The substrate processing apparatus of claim 5, wherein the second direct current power source includes a variable direct current power source.
